(19) United States
(12) Patent Application Publication
(10) Pub. No.: US 2010/0104959 A1
(43) Pub. Date: Apr. 29, 2010

(54) LITHOGRAPHIC METHOD, APPARATUS AND CONTROLLER

(75) Inventors: Rik Teodoor Vangheluwe, Bergeijk (NL); Stephan Ewald Sinkwitz, Wuppertal (DE); Rudy Jan Maria Pellens, Overpelt (BE); Ralf Martinus Marinus Daverveld, Sint-Oedenrode (NL)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 12/582,735

(22) Filed: Oct. 21, 2009

Related U.S. Application Data
(60) Provisional application No. 61/193,038, filed on Oct. 23, 2008.

(51) Int. Cl. G03F 7/20; G03B 27/54; G05B 13/04

(52) U.S. Cl. 430/30; 355/67; 700/121

(57) ABSTRACT

A method for lithographically applying a pattern to a substrate involves obtaining temperature as a function of time during a post exposure bake for one or more locations on a substrate coated with a layer of chemically amplified resist. A relationship between radiation dosage directed onto the chemically amplified resist and post-exposure concentration of accelerant generated in the chemically amplified resist layer by the radiation dosage is also obtained. Using a model relating the critical dimension to post-exposure concentration of accelerant, and temperature as a function of time across the one or more locations, a radiation dosage to obtain a specified critical dimension for the patterned substrate can be calculated. A substrate can be patterned using the calculated radiation dosage for each one or more location on the substrate such that a specified critical dimension is obtained. An apparatus and controller for putting the method into effect are also disclosed.

This application claims priority and benefit under 35 U.S.C. §119(e) to U.S. Provisional Patent Application No. 61/193,038, entitled “Lithographic Method, Apparatus and Controller”, filed on Oct. 23, 2008. The content of that application is incorporated herein in its entirety by reference.

### FIELD

The present invention relates to a lithographic apparatus and a device manufacturing method.

### BACKGROUND

A lithographic apparatus is a machine that applies a desired pattern onto a target portion of a substrate. Lithographic apparatus can be used, for example, in the manufacture of integrated circuits (ICs). In that circumstance, a patterning device, which is alternatively referred to as a mask or a reticle, may be used to generate a circuit pattern corresponding to an individual layer of the IC, and this pattern can be imaged onto a target portion (e.g. comprising part of, one or several dies) on a substrate (e.g. a silicon wafer) that has a layer of radiation-sensitive material (resist). In general, a single substrate will contain a network of adjacent target portions that are successively exposed. Known lithographic apparatus include so-called steppers, in which each target portion is irradiated by exposing an entire pattern onto the target portion in one go, and so-called scanners, in which each target portion is irradiated by scanning the pattern through the beam in a given direction (the “scanning”-direction) while synchronously scanning the substrate parallel or anti-parallel to this direction.

The resist is typically coated onto the substrate by a method such as spin coating used to provide a thin uniform film across a substrate surface. After coating, the substrate is typically pre-baked to make the resist solid and stable. The resist is then patterned, by exposure to radiation using a lithographic apparatus as detailed above, to provide a latent image in the resist. In response to the exposure, a positive resist leaves behind an image that matches the image of the mask used to expose the resist, whereas a negative resist leaves behind an image that is the reverse of the mask. Subsequently, a developer is applied to the exposed resist coating to remove exposed positive resist or unexposed negative resist. This exposes the substrate which may be patterned by etching or otherwise, where it is not protected by remaining resist.

Chemically amplified resists (CARs) allow images of pattern features with a size smaller than 0.2 μm to be provided on substrates. After the exposure to provide a latent image, chemically amplified resists are heated in a post-exposure bake (PEB) and usually subsequently chilled to stop reaction prior to development and/or further processing of the resist and the substrate. For a positive resist, the exposed portions of the resist become soluble and can be readily removed by means of a developer.

More specifically, during the exposure to radiation of a chemically amplified resist, molecules of an accelerant are formed, which subsequently react with the resist to modify the solubility of the resist to developer. The accelerant may be, for instance, a catalyst or a reactant which is formed on exposure, and/or formed after exposure during a post-exposure bake. For instance, a typical chemically amplified resist is an acid catalyzed resist, which has an acid catalyst formed on exposure to radiation inside the exposed portions of the resist. This reacts with other components in the resist to make the resist base-soluble and readily dissolved after a subsequent post-exposure bake (PEB).

Manufacturers conventionally specify key attributes of a desired pattern, such as for example the critical dimension (CD) of an exposed pattern or a printed pattern. This CD may be used to characterize a feature size or a parameter related to the topography (profile) of a feature as present in the pattern. The critical dimension CD can be used to establish a benchmark level of quality and uniformity (e.g. a spatial variability of feature size over a die, or a substrate). It is desirable that a critical dimension and profile of features of the pattern exposed on a resist on a substrate are replicated as accurately as possible. The CD metric may include, for instance, a gap between features, a diameter of holes and/or posts, ellipticity of holes and/or posts, areas of features, feature sidewall angle, width at a top of a feature, width at a bottom of a feature and a line edge roughness.

### SUMMARY

Variations in CD across a substrate may lead to loss in yield if the CD at some locations on the resulting pattern differs beyond tolerance from a desired CD or exceeds that CD which would be required for effectiveness of the exposed pattern. When effecting lithographic patterning using chemically amplified resists, the resulting CD may vary across different locations on the patterned substrate.

Accordingly, it would be desirable to provide a lithography apparatus and/or method, which allowed for mitigation or obviation of one or more problems in the prior art, such as relating to variability in CD across a patterned substrate, whether mentioned herein or elsewhere.

The chemical reaction and the diffusion of the radiation-generated accelerant in a chemically amplified resist, in and from exposed regions of resist, may have an effect on the resulting CD at any particular location on a substrate, and any variations in temperature across a substrate during the PEB/chill steps of processing of a substrate may lead to undesired variations in the CD obtained at different locations on a substrate.

Although the performance of PEB heaters has been improved to give good uniformity across a substrate, the remaining temperature non-uniformity in the PEB step may give a contribution of up to 0.8 nm to the critical dimension.

When a chemically amplified resist is heated during PEB, at least two types of process may take place. The first is a chemical reaction within the resist matrix, modified or catalyzed by the radiation-generated accelerant. In a positive resist, for instance, this renders resist matrix in exposed areas more soluble to developer. The second process is the thermally driven diffusion of accelerant that will depend upon the post-exposure concentration of accelerant in various exposed areas of resist. The post-exposure accelerant concentration in a resist layer on entry into the PEB/chill step will depend upon the radiation exposure dosage applied to the chemically amplified resist at each location of a resist layer.

The chemical reaction, as well as the diffusion, at any particular location in a resist layer, will be determined by the local temperature during the PEB/chill process and a local concentration of radiation-generated accelerant. This is because the temperature at any location, and its variation with time during the PEB step, will influence the chemical reactions modulated by the accelerant and the diffusion of the accelerant.

In an embodiment of the invention, there is provided a method for lithographically applying a pattern to a substrate comprising:

a) obtaining temperature as a function of time during a post exposure bake step for one or more locations on a test substrate coated with a test layer of a chemically amplified resist,

b) obtaining a relationship between a radiation dosage directed onto the chemically amplified resist and a post-exposure concentration of an accelerant generated in the chemically amplified resist by the radiation dosage,

c) calculating a radiation dosage for the one or more locations to obtain a specified critical dimension at each one or more location, by means of a model relating the critical dimension to post-exposure concentration of accelerant, and temperature as a function of time at each of the one or more locations during the post-exposure bake step, and

d) patterning the substrate coated with a layer of the chemically amplified resist, by using the calculated radiation dosage for each of the one or more locations on the substrate equivalent to corresponding locations on the test substrate.

The temperature as a function of time during the post-exposure bake may be obtained by measurement on a test substrate subjected to the substantially same post-exposure baking conditions. However, it may be that such information is obtained from a supplier of post-exposure bake apparatus. The relationship between radiation dosage and post-exposure concentration of accelerant for the resist may be measured, for instance using a test layer of resist, or may be known from elsewhere, such as from the chemically amplified resist's supplier's literature.

The test substrate is suitably similar to the substrate to be patterned; desirably it is substantially identical to the substrate. The test layer of CAR on the test substrate is suitably similar to the CAR layer of the substrate to be patterned, desirably substantially identical.

The model suitably accounts for chemical reaction and diffusion of the radiation-generated accelerant during the post-exposure bake step. By “post-exposure bake step” or “PEB step” is meant a process step in which the substrate, with a CAR layer which has been exposed to radiation, is heated to a suitable temperature to allow the desired chemical reaction amplifying the effect of exposure to take place. The substrate enters the post-exposure bake step having a post-exposure concentration of radiation-generated accelerant at each of the one or more locations on the substrate. At the end of the PEB step, before the substrate is transported through the apparatus and process for development and further processing, the CAR is typically chilled to a temperature at which no further significant chemical reaction or diffusion takes place. This is generally called “chilling”. The term “post-exposure bake step” as used herein also includes any chilling of the resist prior to developing the pattern on the substrate.

Suitably, the chemically amplified resist is an acid catalyzed resist.

The specified critical dimension at each one or more location may be the same or substantially the same for each location, whereby uniform critical dimension across the patterned substrate is obtained.

In an embodiment of the invention, there is provided a lithographic apparatus comprising an illumination system configured to project patterning radiation having a radiation dosage onto each of a plurality of locations onto a substrate coated with a chemically amplified resist, the apparatus comprising a controller arranged to adjust the radiation dosage at each of the plurality of locations in accordance with a method of an embodiment of the invention.

In an embodiment of the invention, there is provided a controller for a lithographic apparatus comprising an illumination system configured to project patterning radiation having a radiation dosage onto each of a plurality of locations onto a substrate coated with a chemically amplified resist, the controller being arranged to adjust the radiation dosage at each of the plurality of locations in accordance with a method of an embodiment of the invention.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 depicts a plan view of a substrate of an embodiment of the invention schematically divided into a plurality of locations.

FIG. 3 schematically shows a process layout for an embodiment of the invention.

FIG. 4 shows a schematic flow diagram for a method of an embodiment of the invention.

### DETAILED DESCRIPTION

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

The term “patterning device” used herein should be broadly interpreted as referring to a device that can be used to impart a radiation beam with a pattern in its cross-section such as to create a pattern in a target portion of the substrate. It should be noted that the pattern imparted to the radiation beam may not exactly correspond to the desired pattern in the target portion of the substrate. Generally, the pattern imparted to the radiation beam will correspond to a particular functional layer in a device being created in the target portion, such as an integrated circuit.

A patterning device may be transmissive or reflective. Examples of patterning device include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions; in this manner, the reflected beam is patterned.

A support structure holds the patterning device. It holds the patterning device in a way depending on the orientation of the patterning device, the design of the lithographic apparatus, and other conditions, such as for example whether or not the patterning device is held in a vacuum environment. The support can use mechanical clamping, vacuum, or other clamping techniques, for example electrostatic clamping under vacuum conditions. The support structure may be a frame or a table, for example, which may be fixed or movable as required and which may ensure that the patterning device is at a desired position, for example with respect to the projection system. Any use of the terms “reticle” or “mask” herein may be considered synonymous with the more general term “patterning device”.

The term “projection system” used herein should be broadly interpreted as encompassing various types of projection system, including refractive optical systems, reflective optical systems, and catadioptric optical systems, as appropriate for example for the exposure radiation being used, or for other factors such as the use of an immersion fluid or the use of a vacuum. Any use of the term “projection lens” herein may be considered as synonymous with the more general term “projection system”.

An illumination system may also encompass various types of optical components, including refractive, reflective, and catadioptric optical components for directing, shaping, or controlling the beam of radiation, and such components may also be referred to below, collectively or singularly, as a “lens”.

The lithographic apparatus may be of a type having two (dual stage) or more substrate tables (and/or two or more support structures). In such “multiple stage” machines the additional tables may be used in parallel, or preparatory steps may be carried out on one or more tables while one or more other tables are being used for exposure.

The lithographic apparatus may also be of a type wherein the substrate is immersed in a liquid having a relatively high refractive index, e.g. water, so as to fill a space between the final element of the projection system and the substrate. Immersion techniques are well known in the art for increasing the numerical aperture of projection systems.

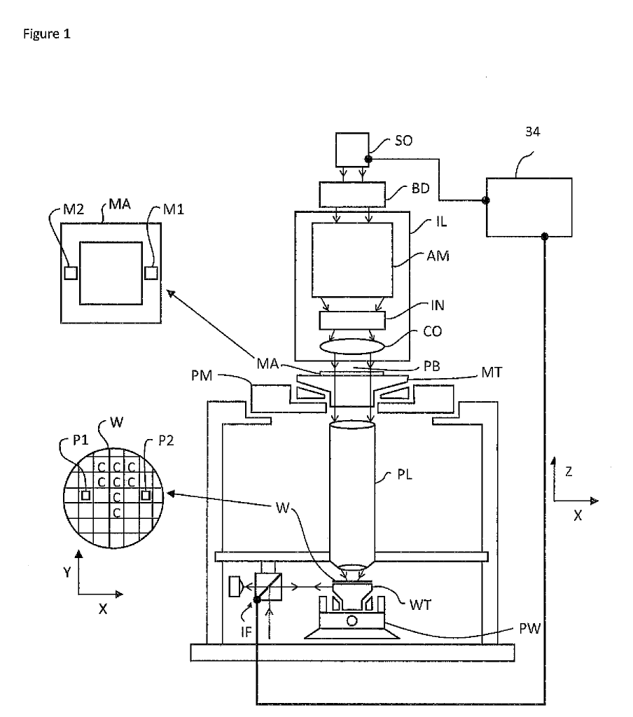

FIG. 1 schematically depicts a lithographic apparatus according to a particular embodiment of the invention. The apparatus comprises:

an illumination system (illuminator) IL to condition a beam PB of radiation (e.g. UV radiation);

a controller 34 arranged to control the radiation dosage of the beam of radiation PB supplied by the illumination system depending upon the location on the substrate to be exposed in accordance with the method of an embodiment of the invention;

a support structure (e.g. a support structure) MT to support a patterning device (e.g. a mask) MA and connected to first positioning device PM to accurately position the patterning device with respect to item PL;

a substrate table (e.g. a wafer table) WT to hold a substrate (e.g. a resist-coated wafer) W and connected to second positioning device PW to accurately position the substrate with respect to item PL; and

a projection system (e.g. a refractive projection lens) PL configured to image a pattern imparted to the radiation beam PB by patterning device MA onto a target portion C (e.g. comprising one or more dies) of the substrate W.

As here depicted, the apparatus is of a transmissive type (e.g. employing a transmissive mask). Alternatively, the apparatus may be of a reflective type (e.g. employing a programmable mirror array of a type as referred to above).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases the source may be integral part of the apparatus, for example when the source is a mercury lamp. The source SO and the illuminator IL, together with the beam delivery system BD if required, may be referred to as a radiation system.

The illuminator IL may comprise adjusting means AM for adjusting the angular intensity distribution of the beam. Generally, at least the outer and/or inner radial extent (commonly referred to as σ-outer and σ-inner, respectively) of the intensity distribution in a pupil plane of the illuminator can be adjusted. In addition, the illuminator IL generally comprises various other components, such as an integrator IN and a condenser CO. The illuminator provides a conditioned beam of radiation PB, having a desired uniformity and intensity distribution in its cross-section.

The radiation beam PB is incident on the patterning device (e.g. mask) MA, which is held on the support structure MT. Having traversed the patterning device MA, the beam PB passes through the projection system PL, which focuses the beam onto a target portion C of the substrate W. With the aid of the second positioning device PW and position sensor IF (e.g. an interferometric device), the substrate table WT can be moved accurately, e.g. so as to position different target portions C in the path of the beam PB. Similarly, the first positioning device PM and another position sensor (which is not explicitly depicted in FIG. 1) can be used to accurately position the patterning device MA with respect to the path of the beam PB, e.g. after mechanical retrieval from a mask library, or during a scan. In general, movement of the object tables MT and WT will be realized with the aid of a long-stroke module (coarse positioning) and a short-stroke module (fine positioning), which form part of the positioning device PM and PW. However, in the case of a stepper (as opposed to a scanner) the support structure MT may be connected to a short stroke actuator only, or may be fixed. Patterning device MA and substrate W may be aligned using patterning device alignment marks M1, M2 and substrate alignment marks P1, P2.

The depicted apparatus can be used in the following modes:

1. In step mode, the support structure MT and the substrate table WT are kept essentially stationary, while an entire pattern imparted to the beam PB is projected onto a target portion C in one go (i.e. a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the support structure MT and the substrate table WT are scanned synchronously while a pattern imparted to the beam PB is projected onto a target portion C (i.e. a single dynamic exposure). The velocity and direction of the substrate table WT relative to the support structure MT is determined by the (de-)magnification and image reversal characteristics of the projection system PL. In scan mode, the maximum size of the exposure field limits the width (in the non-scanning direction) of the target portion in a single dynamic exposure, whereas the length of the scanning motion determines the height (in the scanning direction) of the target portion.

3. In another mode, the support structure MT is kept essentially stationary holding a programmable patterning device, and the substrate table WT is moved or scanned while a pattern imparted to the beam PB is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

In the embodiment shown, the controller 34 is functionally connected to the radiation source SO and the position sensor IF in order to help ensure that the radiation dosage exposure at any particular location on the substrate is in accordance with the method of an embodiment of the invention. In another embodiment, the controller could modify the illuminator IL to control the radiation dosage, rather than directly controlling the intensity of the radiation source SO.

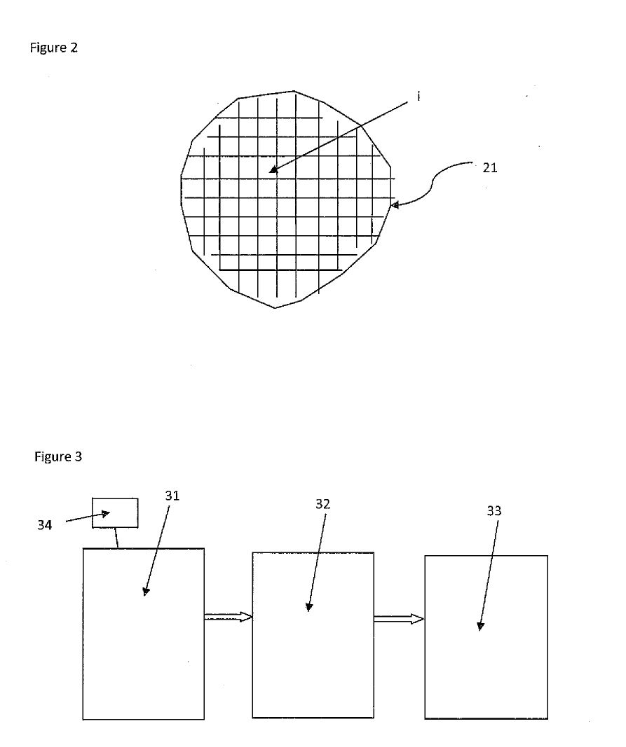

FIG. 2 shows a schematic, plan view of a substrate 21 of an embodiment of the invention, with the surface of the substrate 21 arbitrarily divided into separate locations i by a linear Cartesian grid. It should be noted that the substrate is not physically divided into such locations and that the size and position of the locations i is arbitrary, with the Cartesian grid merely being an example.

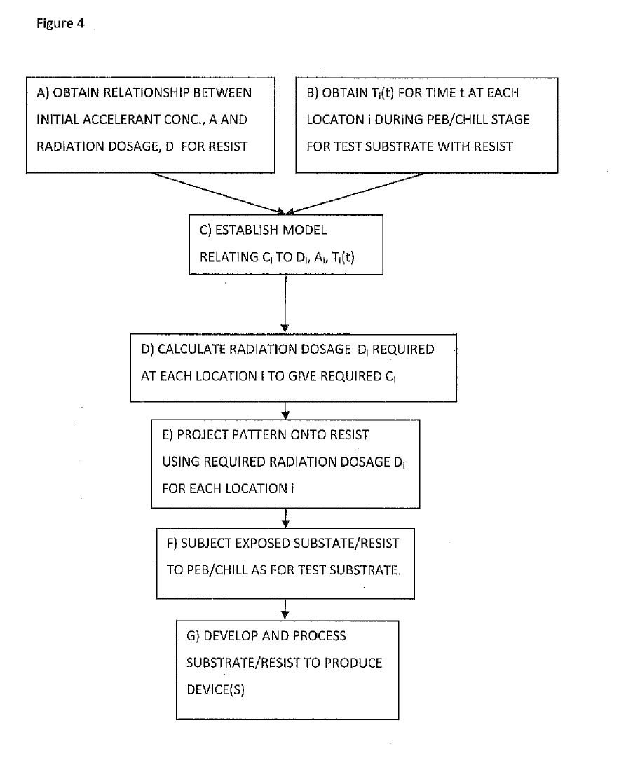

FIG. 2 applies equally to a test substrate or to a substrate to be patterned in the embodiment of the invention, as the test substrate and the substrate to be patterned may be substantially identical. FIG. 2 will be referred to when describing the embodiments of FIGS. 3 and 4.

FIG. 3 shows a schematic view of an embodiment of a process layout for putting an embodiment of the invention into effect. A lithographic apparatus 31, as detailed in FIG. 1 includes a controller 34 in the form of a computer program-driven controller functionally connected to the radiation source SO and position sensor IF such that the method of an embodiment of the invention can be put into effect. A substrate 21 having a CAR layer is exposed to patterned radiation by the apparatus 31. The controller 34 helps ensure that for each location i on the substrate, the dosage (Dᵢ) used for patterning is as specified by means of a model relating the critical dimension to post-exposure concentration of accelerant (Aᵢ), and to temperature as a function of time at each location i during the post-exposure bake step, and from a known relationship between the calculated dosage Di and the post-exposure concentration of accelerant Aᵢ

The substrate 21 is next transported, by means of a so-called wafer or substrate track apparatus, to a PEB/chill unit 32, i.e., device arranged for applying a PES process followed by a chill step. Here, the exposed substrate is subjected to substantially the same PEB/chill conditions as for the test substrate, such that the temperature, as a function of time, for each location i on the substrate 21 is substantially identical to that for the test substrate.

After processing the substrate in the PEB/chill unit 32, the wafer track delivers the substrate to a development and further processing unit 33 where the substrate is developed and processed to provide a printed pattern in resist including pattern features having the specified critical dimension Cᵢ.

FIG. 4 shows a schematic flow chart for the embodiment of the invention shown in FIGS. 1 to 3.

Process step A is the obtaining of a relationship between the initial, post-exposure accelerant concentration A and the radiation dosage D applied to the resist. This relation may be expressed by Equation I

A=φ(D) I

where φ is a function relating post-exposure accelerant concentration A to exposure dosage D. This may be obtained by separate measurement and analytical techniques, or may be well known for the CAR and the radiation type being used in the embodiment, for instance from supplier literature.

Step B is the obtaining of the temperature for each location i on the substrate 21 as a function of time during the PEB/chill process step. This can be expressed as temperature Tᵢ(t) for each location i, where time t varies from t₀ at the beginning of the PEB/chill process step to t_{f} at the end of the PEB chill process step. A spatial distribution or a variability across the substrate of temperatures as well as temperature time-dependencies may be measured for a test substrate. Alternatively or additionally, for instance, such information may be provided by a supplier along with the PEB/chill apparatus. The test substrate is desirably substantially identical to the substrate(s) to be patterned, and coated with the substantially the same CAR in a layer substantially identical to the CAR layer to be used with the substrates to be patterned.

Conventional methods are used to monitor the temperature during the PEB/chill process for the test substrate. For instance thermocouples may be used. It is nowadays possible to control the PEB/chill process with extremely high reproducibility so that the temperature Tᵢ(t) for the substrate to be patterned will be substantially identical to temperature Tᵢ(t) for the test substrate provided that the test substrate and test CAR layer are substantially identical to the substrate to be patterned and its CAR layer. It may not be necessary to measure directly the temperature Tᵢ(t) for each location i. Instead, the temperature may be measured at a number of other locations and interpolated to derive Tᵢ(t).

Step C is the establishment of a model relating a critical dimension Cᵢ at each location i to the post-exposure accelerant concentration Aᵢ at each location i and Tᵢ(t). A typical model would have the form of equation II

Cᵢ=∫ₜ_{₀}^{t}^{_{f}}F(Aᵢ, Tᵢ(t))dt II

In this equation, F represents a function detailing how the critical dimension Cᵢ evolves over time during the post-exposure bake and chill depending upon the local values of post-exposure accelerant concentration Aᵢ and temperature Tᵢ(t). Where Aᵢ=φ(Dᵢ) so it is possible to derive a value to set for Dᵢ in order to give a specified Cᵢ from knowledge of Tᵢ(t) from the model relating Cᵢ to Aᵢ and Tᵢ(t) can be established.

Various suitable models could be used. See for instance the models proposed in published U.S. Pat. No. 5,717,612, or the models proposed in U.S. Pat. No. 6,295,637.

It may be desirable to use a simplified model, such as in equation III:

Cᵢ=ψ(Aᵢ)∫ₜ_{₀}^{t}^{_{f}}R(Tᵢ(t))dt III

In this model, Ψ is a function representing how the critical dimension Cᵢ at location i depends upon the initial post-exposure accelerant concentration Aᵢ at i, whilst R is a rate function describing how the critical dimension evolves depending upon the local temperature Tᵢ(t) at i as time passes. In the model of equation III, it is assumed that the effect of post-exposure accelerant concentration on critical dimension may be modeled by using a rate constant R, which depends upon the temperature Tᵢ(t). For instance, a simple, so called Q10 model may be used, based on the Arrhenius equation, where the reaction rate is assumed to change by a factor Q for each increase of 10° C. in temperature. Typically a value of 2 is used for the factor Q.

Process step D provides the dosage Dᵢ for each location i, calculated from the model and from equation I, to give the specified critical dimension Cᵢ at each location.

Step E is concerned with the actual patterning of a substrate using the process layout of FIG. 3. The pattern is projected onto a substrate substantially identical to the test substrate and with a layer of CAR substantially identical to that used on the test substrate. The controller 34, programmed in accordance with steps A to D, helps ensure that the radiation dosage Dᵢ for each location i is as needed to give the specified critical dimension Cᵢ according to the model.

In step F, the resulting exposed substrate, with post-exposure accelerant concentration Aᵢ at each location i is subjected to a post-exposure bake and chill lasting from time t₀ to t_{f} as for the test substrate. Finally, the substrate and CAR are developed and processed in step G to yield devices with the specified critical dimension Cᵢ for each location i on the substrate.

Once the steps A to C have been established for a particular system, it is possible to repeat steps D to G for as many substrates with CAR layers as required, without needing to repeat steps A to C, provided that the substrates used remain substantially identical to the test substrate and its CAR layer, and provided that the PEB/chill process step remains substantially unchanged.

While specific embodiments of the invention have been described above, it will be appreciated that the invention may be practiced otherwise than as described. The description is not intended to limit the invention.

1. A method for lithographically applying a pattern to a substrate comprising:
calculating a radiation dosage for one or more locations on a substrate coated with a layer of a chemically amplified resist to obtain a specified critical dimension at each one or more location, by means of a model relating the critical dimension to post-exposure concentration of accelerant generated in chemically amplified resist, and temperature as a function of time at each of the one or more locations during a post-exposure bake step, and by means of a relationship between radiation dosage directed onto chemically amplified resist and post-exposure concentration of accelerant generated in such chemically amplified resist by such radiation dosage; and
patterning the substrate coated with the layer of the chemically amplified resist, by using the calculated radiation dosage for each of the one or more locations on the substrate.

2. The method of claim 1, further comprising obtaining the temperature as a function of time during a post exposure bake step for one or more locations on a test substrate coated with a test layer of chemically amplified resist, and patterning the substrate coated with the layer of the chemically amplified resist, by using the calculated radiation dosage for each of the one or more locations on the substrate equivalent to corresponding locations on the test substrate.

3. The method of claim 2, wherein the test substrate is substantially identical to the substrate to be patterned.

4. The method of claim 2, wherein the test layer of chemically amplified resist is substantially identical to the layer of chemically amplified resist coated onto the substrate to be patterned.

5. The method of claim 1, wherein the model accounts for chemical reaction and diffusion of the accelerant during the post-exposure bake step.

6. The method of claim 1, wherein the post-exposure bake step includes chilling of the chemically amplified resist prior to developing the pattern on the substrate.

7. The method of claim 1, wherein the chemically amplified resist is an acid catalyzed resist.

8. The method of claim 1, wherein the specified critical dimension at each one or more location is the same for each one or more location.

9. A lithographic apparatus comprising an illumination system configured to project patterning radiation having a radiation dosage onto each of a plurality of locations onto a substrate coated with a chemically amplified resist, the apparatus comprising a controller configured to adjust the radiation dosage at each of the plurality of locations by:
calculating a radiation dosage for the one or more locations to obtain a specified critical dimension at each one or more location, by means of a model relating the critical dimension to post-exposure concentration of accelerant generated in chemically amplified resist, and temperature as a function of time at each of the one or more locations during a post-exposure bake step, and by means of a relationship between radiation dosage directed onto chemically amplified resist and post-exposure concentration of accelerant generated in such chemically amplified resist by such radiation dosage, and
patterning the substrate coated with the chemically amplified resist, by using the calculated radiation dosage for each of the one or more locations on the substrate.

10. The lithographic apparatus of claim 9, wherein the controller is configured to obtain the temperature as a function of time during a post exposure bake step for one or more locations on a test substrate coated with a test layer of chemically amplified resist.

11. The lithographic apparatus of claim 9, wherein the controller is configured to obtain the relationship between radiation dosage directed onto chemically amplified resist and post-exposure concentration of accelerant generated in such chemically amplified resist by such radiation dosage.

12. The lithographic apparatus of claim 9, wherein the model accounts for chemical reaction and diffusion of the accelerant during the post-exposure bake step.

13. The lithographic apparatus of claim 9, wherein the post-exposure bake step includes chilling of the chemically amplified resist prior to developing the pattern on the substrate.

14. A controller for a lithographic apparatus comprising an illumination system configured to project patterning radiation having a radiation dosage onto each of a plurality of locations onto a substrate coated with a chemically amplified resist, the controller configured to adjust the radiation dosage at each of the plurality of locations by:
calculating a radiation dosage for the one or more locations to obtain a specified critical dimension at each one or more location, by means of a model relating the critical dimension to post-exposure concentration of accelerant generated in chemically amplified resist, and temperature as a function of time at each of the one or more locations during a post-exposure bake step, and by means of a relationship between radiation dosage directed onto chemically amplified resist and post-exposure concentration of accelerant generated in such chemically amplified resist by such radiation dosage, and
patterning the substrate coated with the chemically amplified resist, by using the calculated radiation dosage for each of the one or more locations on the substrate.

15. The controller of claim 14, wherein the controller is configured to obtain temperature as a function of time during a post exposure bake step for one or more locations on a test substrate coated with a test layer of chemically amplified resist.

16. The controller of claim 14, wherein the controller is configured to obtain the relationship between radiation dosage directed onto chemically amplified resist and post-exposure concentration of accelerant generated in such chemically amplified resist by such radiation dosage.

17. The controller of claim 14, wherein the model accounts for chemical reaction and diffusion of the accelerant during the post-exposure bake step.

18. The controller of claim 14, wherein the post-exposure bake step includes chilling of the chemically amplified resist prior to developing the pattern on the substrate.
